(19) United States
(12) Patent Application Publication
(10) Pub. No.: US 2025/0335012 A1
(43) Pub. Date: Oct. 30, 2025

(54) EDGE DATA CENTER WITH INTEGRATED GEOTHERMAL COOLING

(71) Applicant: INTERNATIONAL BUSINESS MACHINES CORPORATION, ARMONK, NY (US)

(72) Inventors: DUSTIN DEMETRIOU, HYDE PARK, NY (US); JOHN TOROK, POUGHKEEPSIE, NY (US); JOHN S. WERNER, FISHKILL, NY (US); ARKADIY O. TSFASMAN, WAPPINGERS FALLS, NY (US); NOAH SINGER, WHITE PLAINS, NY (US)

(21) Appl. No.: 18/646,921

(22) Filed: Apr. 26, 2024

(51) Int. Cl. G06F 1/20; H05K 7/20

(52) U.S. Cl. CPC G06F 1/206; H05K 7/20245; H05K 7/20272; H05K 7/20281

(57) ABSTRACT

Methods, systems, and products for edge data center integrated geothermal cooling include an edge data center container including: computing equipment, and a heat exchanger coupled to the computing equipment via a thermosiphon; a fluid reservoir positioned underground below the edge data center container, wherein the fluid reservoir is configured for geothermal cooling; and a pump configured to circulate cooling fluid between the fluid reservoir and the heat exchanger.

### BACKGROUND

### Field of the Disclosure

The field of the disclosure is data processing, or, more specifically, methods, systems, and products for edge data center integrated geothermal cooling.

### Description of Related Art

Edge data centers are often located in regions where providing high density cooling may be difficult. Even when cooling can be provided, the distribution of electricity can pose a challenge in remote environments. To support the proliferation of edge data centers globally, a more efficient and scalable design is needed.

### SUMMARY

Methods, apparatus, and systems for system edge data center integrated geothermal cooling according to various embodiments are disclosed in this specification. In accordance with one aspect of the present disclosure, a system for edge data center integrated geothermal cooling may include an edge data center container including: computing equipment, and a heat exchanger coupled to the computing equipment via a thermosiphon; a fluid reservoir positioned underground below the edge data center container, wherein the fluid reservoir is configured for geothermal cooling; and a pump configured to circulate cooling fluid between the fluid reservoir and the heat exchanger.

In accordance with another aspect of the present disclosure, a method of cooling edge data center equipment may include circulating, via a pump, a cooling fluid between a fluid reservoir and a heat exchanger included in an edge data center container, where the heat exchanger is thermally coupled to computing equipment included in the edge data center container via a thermosiphon; and adjusting, by a pump controller included on the pump, a pump speed of the cooling fluid based on a received instruction.

The foregoing and other objects, features and advantages of the disclosure will be apparent from the following more particular descriptions of exemplary embodiments of the disclosure as illustrated in the accompanying drawings wherein like reference numbers generally represent like parts of exemplary embodiments of the disclosure.

### BRIEF DESCRIPTION OF THE DRAWINGS

FIG. 1 shows an example line drawing of a system configured for edge data center integrated geothermal cooling in accordance with embodiments of the present disclosure.

FIG. 2 is a block diagram of an example computing environment configured for edge data center integrated geothermal cooling according to some embodiments of the present disclosure.

FIG. 3 is a flowchart of an example method for edge data center integrated geothermal cooling according to some embodiments of the present disclosure.

FIG. 4 is a flowchart of another example method for edge data center integrated geothermal cooling according to some embodiments of the present disclosure.

FIG. 5 is a flowchart of another example method for edge data center integrated geothermal cooling according to some embodiments of the present disclosure.

### DETAILED DESCRIPTION

In accordance with one aspect of the present disclosure, a system for edge data center integrated geothermal cooling may include an edge data center container including: computing equipment, and a heat exchanger coupled to the computing equipment via a thermosiphon; a fluid reservoir positioned underground below the edge data center container, wherein the fluid reservoir is configured for geothermal cooling; and a pump configured to circulate cooling fluid between the fluid reservoir and the heat exchanger. Such an embodiment allows for increased cooling efficiency and cooling performance by using geothermal cooling to help cool the computing equipment within an edge data center container.

In another embodiment, the system further includes one or more reservoir heat pipes positioned underground and partially within the fluid reservoir and configured to cool the cooling fluid within the fluid reservoir via geothermal cooling. Such an embodiment provides increased geothermal cooling by utilizing heat pipes (cooled by geothermal cooling) that in turn cool the fluid in the reservoir.

In another embodiment, each of the one or more reservoir heat pipes includes cooling fins positioned within the fluid reservoir. Such an embodiment provides increased heat transfer and cooling between the heat pipes and the cooling fluid in the fluid reservoir.

In another embodiment, the system further includes a fluid return line configured to direct fluid from the heat exchanger back into the fluid reservoir. Such an embodiment allows for increased cooling efficiency by circulating the fluid through the heat exchanger and back into the reservoir.

In another embodiment, the system further includes one or more underground heat pipes coupled directly to the heat exchanger. Such an embodiment provides additional geothermal cooling for the heat exchanger.

In another embodiment, the pump includes a pump controller configured to adjust a pump speed of the pump. Such an embodiment allows for adjusting the speed of fluid circulation and cooling.

In another embodiment, the pump controller is configured to adjust the pump speed based on one or more of a current environment temperature and a predicted future environment temperature. Such an embodiment provides a method of providing a sufficient level of cooling based on the temperatures associated with the edge data center.

In another embodiment, the pump controller is configured to adjust the pump speed based on one or more of a current workload and a predicted future workload. Such an embodiment provides a method of providing a sufficient level of cooling based on the workload of the edge data center.

In another embodiment, the pump controller is configured to adjust the pump speed based on one or more of a current error rate of the computing equipment and a predicted future error rate of the computing equipment. Such an embodiment provides a method of providing a sufficient level of cooling based on the error rate of systems operating within the edge data center.

In accordance with another aspect of the present disclosure, a method of cooling edge data center equipment may include circulating, via a pump, a cooling fluid between a fluid reservoir and a heat exchanger included in an edge data center container, where the heat exchanger is thermally coupled to computing equipment included in the edge data center container via a thermosiphon; and adjusting, by a pump controller included on the pump, a pump speed of the cooling fluid based on a received instruction. Such an embodiment allows for increased cooling efficiency and cooling performance by using geothermal cooling to help cool the computing equipment within an edge data center container.

In accordance with another aspect of the present disclosure, an apparatus for edge data center integrated geothermal cooling includes computing equipment, a thermosiphon coupled to the computing equipment, and a heat exchanger coupled to the computing equipment via the thermosiphon, where the heat exchanger is configured to couple to a fluid reservoir positioned underground, and where a pump circulates cooling fluid between the fluid reservoir and the heat exchanger. Such an embodiment allows for increased cooling efficiency and cooling performance by using geothermal cooling to help cool the computing equipment within an edge data center container.

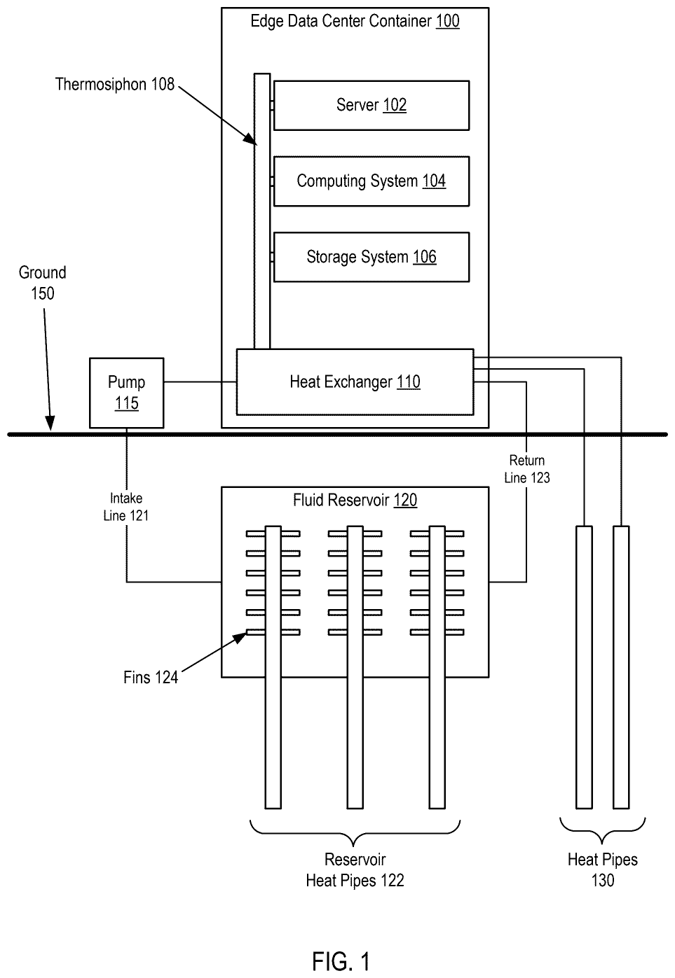

Exemplary methods, systems, and products for edge data center integrated geothermal cooling in accordance with the present disclosure are described with reference to the accompanying drawings, beginning with FIG. 1. FIG. 1 sets forth an example line drawing of a system configured for edge data center integrated geothermal cooling in accordance with embodiments of the present disclosure. The example of FIG. 1 includes an edge data center container 100, a pump 115, and a fluid reservoir 120 positioned under the ground 150 and below the edge data center container.

The example edge data center container 100 of FIG. 1 makes up the structural part of an edge data center that houses the edge data center's computing equipment. The edge data center container may be any type of structure configured to house computing equipment. For example, the edge data center container may comprise a rack, a sealed container, a portable building (such as a shipping container), and the like. The computing equipment included within the edge data center container may be any type of computing equipment, such as servers, computing systems, storage systems, power supplies, fans, network adapters, network switches, and the like. In the example of FIG. 1, the computing equipment included within the edge data center container 100 includes server 102, computing system 104, and storage system 106.

The edge data center container 100 of FIG. 1 also includes a heat exchanger 110. In one embodiment, the heat exchanger 110 is a condenser heat exchanger. In other embodiments, the heat exchanger may be any other type of heat exchanger. The heat exchanger 110 is thermally coupled to each piece of computing equipment (such as server 102, computing system 104, and storage system 106) via a thermosiphon 108. A thermosiphon provides a method of passive heat exchange (using natural convection) by circulating a fluid without the need for a mechanical pump. In another embodiment, a pump could be used with the thermosiphon to add forced convection (versus relying only on natural convection). The example of FIG. 1 shows each piece of computing equipment coupled to the thermosiphon, which is in turn coupled to the heat exchanger 110, allowing the heat exchanger to cool the computing equipment. In one embodiment, the computing equipment is blind docked to the thermosiphon, via fluid connections or valves, allowing computing equipment to be removed or inserted into the thermosiphon without having to power down the entire system and preventing any fluid leaks. In an alternative embodiment, a hose, valve, quick connect, and the like may be manually plugged into the thermosiphon and/or computing equipment during installation or after performing a service or an upgrade.

The system of FIG. 1 also includes a fluid reservoir 120 positioned below the ground 150 under the edge data center container 100. In one embodiment, the fluid reservoir 120 is positioned underground directly below the edge data center container 100. In another embodiment, the fluid reservoir 120 is positioned deep below ground, providing better geothermal cooling effects. In another embodiment, the fluid reservoir 120 is positioned underground but to the side of the edge data center container. The multiple possible positions of the fluid reservoir provide flexibility when installing the system of FIG. 1.

The fluid reservoir 120 of FIG. 1 includes cooling fluid that is circulated, by a pump 115, through the heat exchanger 110 included in the edge data center container 100. The cooling fluid may be any type of cooling fluid, such as water, a water and glycol solution, dielectric fluids, and the like. The fluid reservoir positioned underground provides geothermal cooling to the cooling fluid contained within fluid reservoir. The pump 115 is configured to pump the cooling fluid contained in the fluid reservoir (that has been geothermally cooled) into the heat exchanger 110 via intake line 121 to cool the heat exchanger. After cooling the heat exchanger, the cooling fluid is then circulated by the pump back into the fluid reservoir via a return line 123. By circulating geothermally cooled fluid through the heat exchanger of the edge data center, the edge data center provides additional cooling to the computing equipment using geothermal cooling. Such geothermal cooling does not require additional power (except for the pump) and thus increases system efficiency. The example of FIG. 1 shows a single intake line and a single return line. In other embodiments, there may be multiple sets of intake and return lines, allowing for increased circulation of the cooling fluid and better cooling efficiency. By including additional sets of intake and return lines, the system may achieve similar cooling effects with a lower pump speed (due to the increased circulation), thereby increasing system efficiency. The example of FIG. 1 shows a single pump. In other embodiments, there may be one or more additional pumps for redundancy. In the example of FIG. 1, the pump is shown as being positioned above ground and outside of the edge data center container. In other embodiments, the pump (or pumps) may be positioned inside the edge data center container, on top of the edge data center, mounted on an external surface of the edge data center, and underground.

The fluid reservoir 120 of FIG. 1 includes one or more reservoir heat pipes 122 positioned underground and partially within the fluid reservoir. The reservoir heat pipes 122 are configured to cool the cooling fluid within the fluid reservoir via geothermal cooling. A heat pipe is a heat-transfer device that uses phase transition to transfer heat between two interfaces. A heat pipe is a closed container containing a fluid that undergoes a cycle of evaporation and condensation to provide passive thermal cooling. In one embodiment, the reservoir heat pipes are a type of thermosiphon. The fluid included within the reservoir heat pipes may be any type of cooling fluid, such as water (kept under pressure), alcohol, refrigerant, and the like. By including one or more heat pipes within the fluid reservoir, and which are also partially surrounded by the earth below the reservoir, the heat pipes may provide additional geothermal cooling to the cooling fluid in the reservoir, which in turn provides further cooling to the heat exchanger and the computing equipment. The fluid reservoir 120 is cooled via geothermal means using conductive heat pipes that maintain the temperature of the fluid reservoir at a temperature close to the surrounding earth. The example of FIG. 1 shows three reservoir heat pipes 122. In other embodiments, any number of reservoir heat pipes 122 may be included within the fluid reservoir. In other embodiments, the heat pipes may be retractable and/or telescoping such that the amount of pipe that reaches into the fluid reservoir is controlled. Such embodiments allow for an additional method of controlling the amount of cooling provided to the systems and provide a cheaper cost of electricity compared with running the pump at a different speed.

The reservoir heat pipes 122 of FIG. 1 include one or more fins 124 positioned within the fluid reservoir. The inclusion of fins on the portion of the reservoir heat pipes positioned within the fluid reservoir provides additional surface area for the cooling fluid to contact and thus increases heat transfer between the heat pipes and the cooling fluid. Therefore, including fins on the heat pipes increases the geothermal cooling effects on the heat exchanger and the computing equipment of the edge data center. In other embodiments, the cooling fins are configured to be controlled to retract or fold into the heat pipes to control the amount of cooling provided to the systems and provide a cheaper cost of electricity compared with running the pump at a different speed.

The example of FIG. 1 shows the return line 123 as a single port that introduces the cooling fluid back into the fluid reservoir 120. In another embodiment (not shown in FIG. 1), the return line extends into the fluid reservoir to introduce the cooling fluid back into the reservoir right next to the heat pipes and their included fins. In another embodiment, the return line may be coupled to a perforated line spanning the width of the fluid reservoir that is configured to introduce the cooling fluid back into the fluid reservoir at multiple locations throughout the reservoir (and right next to the heat pipes) to more uniformly and quickly cool the returned cooling fluid.

The system of FIG. 1 also includes one or more underground heat pipes (such as heat pipes 130) coupled directly to the heat exchanger 110. By coupling heat pipes directly to the heat exchanger, additional geothermal cooling is provided to the heat exchanger separate from the circulated cooling fluid from the fluid reservoir, and thus adds an additional method for cooling the heat exchanger and the computing equipment of the edge data center. The example of FIG. 1 shows two heat pipes 130. In other embodiments, any number of heat pipes 130 may be directly coupled to the heat exchanger. In one embodiment, the pump is configured to circulate the cooling fluid between the heat pipes 130 and the heat exchanger 110. In one example, the pump is configured to circulate the cooling fluid from the heat exchanger to each heat pipe 130 individually (as shown in FIG. 1). In another example, the pump is configured to circulate the cooling fluid across all heat pipes 130 before returning the cooling fluid to the heat exchanger for heat transfer. In some embodiments, the heat pipes 130 can be controlled to be disconnected (such as using valves to control how many heat pipes that the cooling fluid flows to among the total set of heat pipes 130) from the heat exchanger to control the amount of cooling provided to the systems and provide a cheaper cost of electricity compared with running the pump at a different speed.

The pump 115 of FIG. 1 includes a pump controller configured to adjust a pump speed of the pump. The pump controller is configured to alter the pump speed based on live and/or predicted workload, computing equipment failures, external temperature around the edge data center container, internal temperatures within the edge data center container, temperatures associated with each piece of computing equipment, and any other parameter or property associated with the edge data center. For example, in order to not waste resources on excessive or unneeded cooling, the pump controller is configured to monitor one or more variables (or predict one or more future variables) and adjust the cooling based on the monitoring. In one embodiment, the pump controller is configured to adjust the pump speed based on one or more of a current environment temperature and a predicted future environment temperature. In another embodiment, the pump controller is configured to adjust the pump speed based on one or more of a current workload (executed by the computing equipment of the edge data center) and a predicted future workload. In another embodiment, the pump controller is configured to adjust the pump speed based on one or more of a current error rate of the computing equipment and a predicted future error rate of the computing equipment. For example, if one or more of the computing equipment in the edge data center container starts experiencing a threshold amount of errors, or errors at a threshold error rate, the pump controller is configured to detect the error rate and adjust the pump speed to provide more cooling. Similarly, if the error rate is lower than a threshold, the pump controller may reduce the pump speed to reduce the cooling and thereby save power and resources. In other embodiments, the pump controller is configured to control other properties of the system of FIG. 1 other than pump speed to control the amount of cooling provided to the systems in the edge data center container (such as retracting the reservoir heat pipes 122 from the fluid reservoir, adjusting the fin position of the fins 124, and controlling which and how many heat pipes 130 are coupled to the heat exchanger). In some embodiments, any combination of these properties may be controlled by the pump controller (or any other controller positioned within or remote from the edge data center) to control how much cooling is provided.

In one embodiment, the pump controller is configured to perform the monitoring, and the determination of which pump speed to adjust to. In another embodiment, the pump controller is configured to receive an instruction (such as from a processor included within the edge data center container, or a processor in a separate computing system) indicating a pump speed to adjust the pump to (where the instruction is sent to the pump controller based on the monitoring and determining).

In one embodiment, the pump controller is included in the pump 115. In another embodiment, the pump controller is included within the edge data center container 100. Similarly, the pump 115 may be included within the container or may be positioned separate from the container (as shown in FIG. 1).

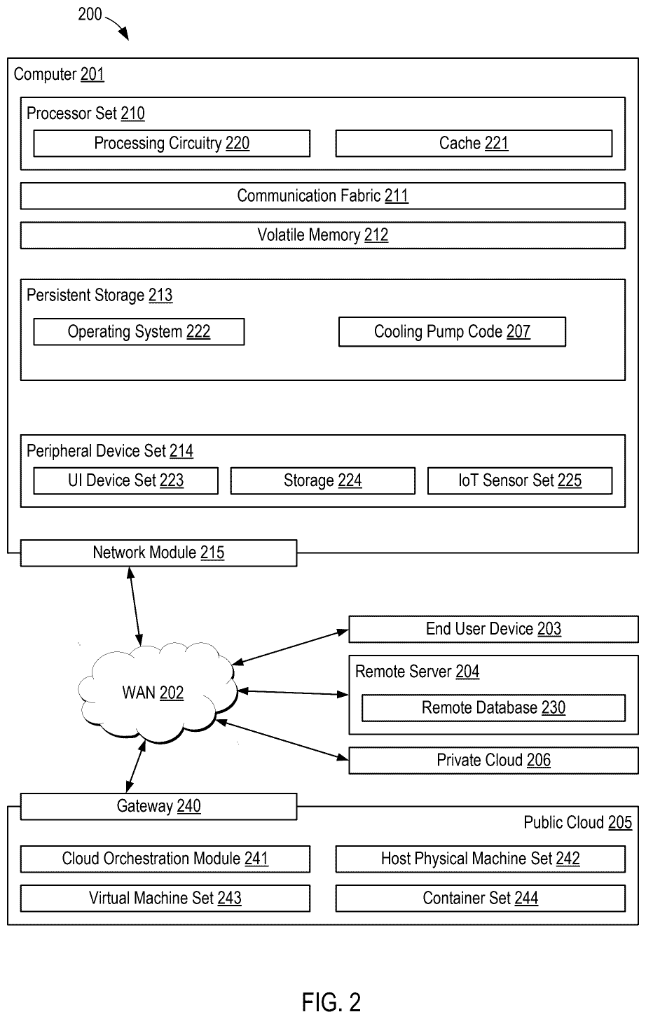

For further explanation, FIG. 2 sets forth a block diagram of computing environment 200 configured for edge data center integrated geothermal cooling in accordance with embodiments of the present disclosure. Computing environment 200 contains an example of an environment for the execution of at least some of the computer code involved in performing the inventive methods, such as cooling pump code 207. In addition to cooling pump code 207, computing environment 200 includes, for example, computer 201, wide area network (WAN) 202, end user device (EUD) 203, remote server 204, public cloud 205, and private cloud 206. In this example embodiment, computer 201 is a computing system included within the edge data center container 100 of FIG. 1, and includes processor set 210 (including processing circuitry 220 and cache 221), communication fabric 211, volatile memory 212, persistent storage 213 (including operating system 222 and cooling pump code 207, as identified above), peripheral device set 214 (including user interface (UI) device set 223, storage 224, and Internet of Things (IoT) sensor set 225), and network module 215. Remote server 204 includes remote database 230. Public cloud 205 includes gateway 240, cloud orchestration module 241, host physical machine set 242, virtual machine set 243, and container set 244.

Computer 201 may take the form of a desktop computer, laptop computer, tablet computer, smart phone, mainframe computer, quantum computer or any other form of computer or mobile device now known or to be developed in the future that is capable of running a program, accessing a network or querying a database, such as remote database 230. As is well understood in the art of computer technology, and depending upon the technology, performance of a computer-implemented method may be distributed among multiple computers and/or between multiple locations. On the other hand, in this presentation of computing environment 200, detailed discussion is focused on a single computer, specifically computer 201, to keep the presentation as simple as possible. Computer 201 may be located in a cloud, even though it is not shown in a cloud in FIG. 2. On the other hand, computer 201 is not required to be in a cloud except to any extent as may be affirmatively indicated.

Processor set 210 includes one, or more, computer processors of any type now known or to be developed in the future. Processing circuitry 220 may be distributed over multiple packages, for example, multiple, coordinated integrated circuit chips. Processing circuitry 220 may implement multiple processor threads and/or multiple processor cores. Cache 221 is memory that is located in the processor chip package(s) and is typically used for data or code that should be available for rapid access by the threads or cores running on processor set 210. Cache memories are typically organized into multiple levels depending upon relative proximity to the processing circuitry. Alternatively, some, or all, of the cache for the processor set may be located “off chip.” In some computing environments, processor set 210 may be designed for working with qubits and performing quantum computing.

Computer readable program instructions are typically loaded onto computer 201 to cause a series of operational steps to be performed by processor set 210 of computer 201 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 221 and the other storage media discussed below. The program instructions, and associated data, are accessed by processor set 210 to control and direct performance of the inventive methods. In computing environment 200, at least some of the instructions for performing the inventive methods may be stored in cooling pump code 207 in persistent storage 213.

Communication fabric 211 is the signal conduction path that allows the various components of computer 201 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 212 is any type of volatile memory now known or to be developed in the future. Examples include dynamic type random access memory (RAM) or static type RAM. Typically, volatile memory 212 is characterized by random access, but this is not required unless affirmatively indicated. In computer 201, the volatile memory 212 is located in a single package and is internal to computer 201, but, alternatively or additionally, the volatile memory may be distributed over multiple packages and/or located externally with respect to computer 201.

Persistent storage 213 is any form of non-volatile storage for computers that is now known or to be developed in the future. The non-volatility of this storage means that the stored data is maintained regardless of whether power is being supplied to computer 201 and/or directly to persistent storage 213. Persistent storage 213 may be a read only memory (ROM), but typically at least a portion of the persistent storage allows writing of data, deletion of data and re-writing of data. Some familiar forms of persistent storage include magnetic disks and solid state storage devices. Operating system 222 may take several forms, such as various known proprietary operating systems or open source Portable Operating System Interface-type operating systems that employ a kernel. The code included in cooling pump code 207 typically includes at least some of the computer code involved in performing the inventive methods.

Peripheral device set 214 includes the set of peripheral devices of computer 201. Data communication connections between the peripheral devices and the other components of computer 201 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 223 may include components such as a display screen, speaker, microphone, wearable devices (such as goggles and smart watches), keyboard, mouse, printer, touchpad, game controllers, and haptic devices. Storage 224 is external storage, such as an external hard drive, or insertable storage, such as an SD card. Storage 224 may be persistent and/or volatile. In some embodiments, storage 224 may take the form of a quantum computing storage device for storing data in the form of qubits. In embodiments where computer 201 is required to have a large amount of storage (for example, where computer 201 locally stores and manages a large database) then this storage may be provided by peripheral storage devices designed for storing very large amounts of data, such as a storage area network (SAN) that is shared by multiple, geographically distributed computers. IoT sensor set 225 is made up of sensors that can be used in Internet of Things applications. For example, one sensor may be a thermometer and another sensor may be a motion detector.

Network module 215 is the collection of computer software, hardware, and firmware that allows computer 201 to communicate with other computers through WAN 202. Network module 215 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 215 are performed on the same physical hardware device. In other embodiments (for example, embodiments that utilize software-defined networking (SDN)), the control functions and the forwarding functions of network module 215 are performed on physically separate devices, such that the control functions manage several different network hardware devices. Computer readable program instructions for performing the inventive methods can typically be downloaded to computer 201 from an external computer or external storage device through a network adapter card or network interface included in network module 215. Network module 215 may be configured to communicate with other systems or devices, such as sensors 225, for receiving sensor measurements.

WAN 202 is any wide area network (for example, the internet) capable of communicating computer data over non-local distances by any technology for communicating computer data, now known or to be developed in the future. In some embodiments, the WAN 202 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 203 is any computer system that is used and controlled by an end user (for example, a customer of an enterprise that operates computer 201), and may take any of the forms discussed above in connection with computer 201. EUD 203 typically receives helpful and useful data from the operations of computer 201. For example, in a hypothetical case where computer 201 is designed to provide a recommendation to an end user, this recommendation would typically be communicated from network module 215 of computer 201 through WAN 202 to EUD 203. In this way, EUD 203 can display, or otherwise present, the recommendation to an end user. In some embodiments, EUD 203 may be a client device, such as thin client, heavy client, mainframe computer, desktop computer and so on.

Remote server 204 is any computer system that serves at least some data and/or functionality to computer 201. Remote server 204 may be controlled and used by the same entity that operates computer 201. Remote server 204 represents the machine(s) that collect and store helpful and useful data for use by other computers, such as computer 201. For example, in a hypothetical case where computer 201 is designed and programmed to provide a recommendation based on historical data, then this historical data may be provided to computer 201 from remote database 230 of remote server 204.

Public cloud 205 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 205 is performed by the computer hardware and/or software of cloud orchestration module 241. The computing resources provided by public cloud 205 are typically implemented by virtual computing environments that run on various computers making up the computers of host physical machine set 242, which is the universe of physical computers in and/or available to public cloud 205. The virtual computing environments (VCEs) typically take the form of virtual machines from virtual machine set 243 and/or containers from container set 244. It is understood that these VCEs may be stored as images and may be transferred among and between the various physical machine hosts, either as images or after instantiation of the VCE. Cloud orchestration module 241 manages the transfer and storage of images, deploys new instantiations of VCEs and manages active instantiations of VCE deployments. Gateway 240 is the collection of computer software, hardware, and firmware that allows public cloud 205 to communicate through WAN 202.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 206 is similar to public cloud 205, except that the computing resources are only available for use by a single enterprise. While private cloud 206 is depicted as being in communication with WAN 202, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 205 and private cloud 206 are both part of a larger hybrid cloud.

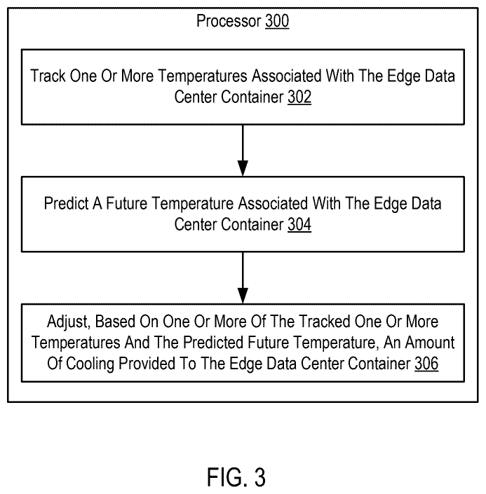

For further explanation, FIG. 3 sets forth a flow chart illustrating an exemplary method of cooling edge data center equipment according to embodiments of the present disclosure. The method of FIG. 3 includes tracking 302 one or more temperatures associated with the edge data center container. Tracking 302 one or more temperatures associated with the edge data center container may be carried out by a processor (such as processor 300) monitoring temperatures such as internal container temperatures, the temperature of each piece of computing equipment, the external environment temperature surrounding the edge data center container, and the like. The processor 300 may be positioned within the edge data center container, in a computing system separate from the edge data center, or may be the pump controller.

The method of FIG. 3 also includes predicting 304 a future temperature associated with the edge data center container. Predicting 304 a future temperature may be carried out by processor 300 based on machine learning, a predictive model, an artificial intelligence model, forecast weather data, trends in edge data center performance, the tracked data of the one or more temperatures, and other variables affecting temperatures. For example, the processor may track the temperatures associated with the edge data center container and may predict, based on the tracking, a future internal temperature of the container that is greater than the current temperature of the container.

The method of FIG. 3 also includes adjusting 306, based on one or more of the tracked one or more temperatures and the predicted future temperature, an amount of cooling provided to the edge data center container. Adjusting 306 an amount of cooling provided to the edge data center container may be carried out by processor 300 in response to determining that one or more of the tracked temperatures or a predicted temperature exceeds a threshold and may include adjusting a pump speed of the cooling fluid. In one example, the processor may increase the pump speed of the cooling fluid to provide additional cooling in response to determining that computing equipment within the container has reached a temperature greater than a threshold. By adjusting the pump speed based on current data center variables, the processor is configured to automatically provide sufficient cooling without wasting resources. In another example, the processor may increase the pump speed of the cooling fluid to provide additional cooling in response to predicting a future temperature (such as a forecasted external environment temperature) that exceeds a threshold. By adjusting the pump speed based on predicted future data center variables, the processor is configured to proactively cool the data center before the data center even reaches a threshold temperature. In another example, the processor may decrease the pump speed of the cooling fluid to save on power consumption and unnecessary cooling in response to determining that the internal temperatures of the edge data center have decreased below a threshold temperature. In other embodiments, the processor 300 is configured to adjust other properties of the system besides pump speed to control the amount of cooling provided to the systems in the edge data center container (such as retracting the reservoir heat pipes from the fluid reservoir, adjusting the fin position of the fins, and controlling which, and how many, heat pipes 130 are coupled to the heat exchanger). In some embodiments, any combination of these properties may be controlled by the processor 300 to control how much cooling is provided.

In some embodiments, as part of the adjusting 306, the processor 300 is configured to extract operating environmental specifications (e.g., a system may be specified to meet ASHRAE class A3 and have an operating range in an ambient temperature range of 5-40C) of the equipment within the edge data center container, and ensure that adjustments are made such that all equipment operates within their respective specified ranges. In some embodiments, computing equipment may be allowed to run hotter than desired by keeping the system closest to the high end of its specified operating range under the limit.

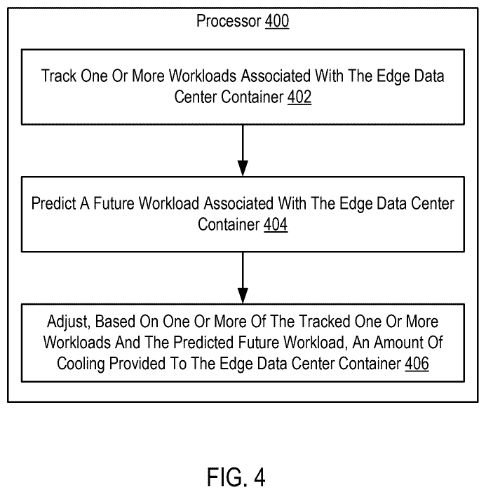

For further explanation, FIG. 4 sets forth a flow chart illustrating another exemplary method of cooling edge data center equipment according to embodiments of the present disclosure. The method of FIG. 4 includes tracking 402 one or more workloads associated with the edge data center container. Tracking 402 one or more workloads associated with the edge data center container may be carried out by a processor (such as processor 400) monitoring workloads of the computing equipment included in the edge data center container. The processor 400 may be positioned within the edge data center container, in a computing system separate from the edge data center, or may be the pump controller.

The method of FIG. 4 also includes predicting 404 a future workload associated with the edge data center container. Predicting 404 a future workload may be carried out by processor 400 based on machine learning, a predictive model, an artificial intelligence model, trends in edge data center performance, the tracked data of the one or more workloads, and other variables affecting workloads. For example, the processor may track the workload associated with the edge data center container and may predict, based on the tracking, a future increased workload of the container that is greater than the current workload of the computing equipment of the edge data center.

The method of FIG. 4 also includes adjusting 406, based on one or more of the tracked one or more workloads and the predicted future workload, an amount of cooling provided to the edge data center container. Adjusting 406 an amount of cooling provided to the edge data center container may be carried out by processor 400 in response to determining that one or more of the tracked workloads or a predicted workload exceeds a threshold and may include adjusting a pump speed of the cooling fluid. In one example, the processor may increase the pump speed of the cooling fluid to provide additional cooling in response to determining that computing equipment within the container is executing a workload larger than a threshold. By adjusting the pump speed based on current data center variables, the processor is configured to automatically provide sufficient cooling without wasting resources. In another example, the processor may increase the pump speed of the cooling fluid to provide additional cooling in response to predicting a future increase in workload that exceeds a threshold. By adjusting the pump speed based on predicted future data center variables, the processor is configured to proactively cool the data center before the data center reaches a threshold temperature. In another example, the processor may decrease the pump speed of the cooling fluid to save on power consumption and unnecessary cooling in response to determining that the workload executing within the edge data center has decreased to below a threshold. In other embodiments, the processor 400 is configured to adjust other properties of the system besides pump speed to control the amount of cooling provided to the systems in the edge data center container (such as retracting the reservoir heat pipes from the fluid reservoir, adjusting the fin position of the fins, and controlling which, and how many, heat pipes 130 are coupled to the heat exchanger). In some embodiments, any combination of these properties may be controlled by the processor 400 to control how much cooling is provided.

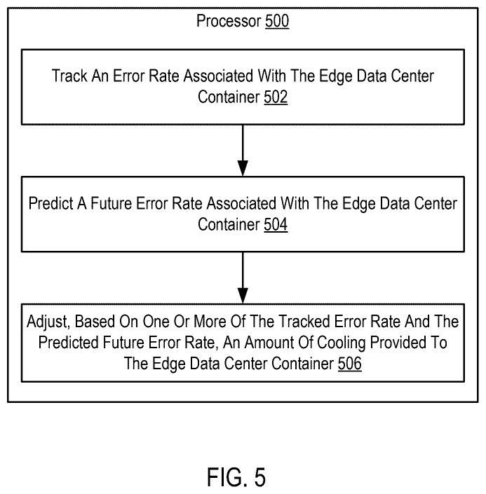

For further explanation, FIG. 5 sets forth a flow chart illustrating another exemplary method of cooling edge data center equipment according to embodiments of the present disclosure. The method of FIG. 5 includes tracking 502 an error rate associated with the edge data center container. Tracking 502 an error rate associated with the edge data center container may be carried out by a processor (such as processor 500) monitoring error rates for the computing equipment included in the edge data center container. The processor 500 may be positioned within the edge data center container, in a computing system separate from the edge data center, or may be the pump controller.

The method of FIG. 5 also includes predicting 504 a future error rate associated with the edge data center container. Predicting 504 a future error rate may be carried out by processor 500 based on machine learning, a predictive model, an artificial intelligence model, trends in edge data center performance, the tracked data of the error rates, and other variables affecting error rates. For example, the processor may track the error rate associated with the edge data center container and may predict, based on the tracking, a future increased error rate of the container that is greater than the current error rate of the computing equipment of the edge data center.

The method of FIG. 5 also includes adjusting 506, based on one or more of the tracked error rate and the predicted future error rate, an amount of cooling provided to the edge data center container. Adjusting 506 an amount of cooling provided to the edge data center container may be carried out by processor 500 in response to determining that the error rate or a predicted future error rate exceeds a threshold and may include adjusting a pump speed of the cooling fluid. In one example, the processor may increase the pump speed of the cooling fluid to provide additional cooling in response to determining that computing equipment within the container has an associated error rate larger than a threshold. By adjusting the pump speed based on current data center variables, the processor is configured to automatically provide sufficient cooling without wasting resources. In another example, the processor may increase the pump speed of the cooling fluid to provide additional cooling in response to predicting a future increased error rate that exceeds a threshold. By adjusting the pump speed based on predicted future data center variables, the processor is configured to proactively cool the data center before the data center reaches a threshold temperature. In another example, the processor may decrease the pump speed of the cooling fluid to save on power consumption and unnecessary cooling in response to determining that an error rate associated with the edge data center has decreased to below a threshold. In other embodiments, the processor 500 is configured to adjust other properties of the system besides pump speed to control the amount of cooling provided to the systems in the edge data center container (such as retracting the reservoir heat pipes from the fluid reservoir, adjusting the fin position of the fins, and controlling which, and how many, heat pipes 130 are coupled to the heat exchanger). In some embodiments, any combination of these properties may be controlled by the processor 500 to control how much cooling is provided.

In view of the explanations set forth above, readers will recognize that the benefits of edge data center integrated geothermal cooling according to embodiments of the present disclosure include:
Increasing cooling efficiency and cooling performance by using geothermal cooling to help cool the computing equipment within an edge data center container.
Increasing system efficiency and performance by preventing overheating of the system and included computing equipment using geothermal cooling.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time. Any combination of the methods of FIGS. 3-5 may be performed.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

It will be understood from the foregoing description that modifications and changes may be made in various embodiments of the present disclosure without departing from its true spirit. The descriptions in this specification are for purposes of illustration only and are not to be construed in a limiting sense. The scope of the present disclosure is limited only by the language of the following claims.

What is claimed is:

1. A system comprising:
an edge data center container including:
computing equipment; and
a heat exchanger coupled to the computing equipment via a thermosiphon;
a fluid reservoir positioned underground below the edge data center container, wherein the fluid reservoir is configured for geothermal cooling; and
a pump configured to circulate cooling fluid between the fluid reservoir and the heat exchanger.

2. The system of claim 1, further comprising one or more reservoir heat pipes positioned underground and partially within the fluid reservoir and configured to cool the cooling fluid within the fluid reservoir via geothermal cooling.

3. The system of claim 2, wherein each of the one or more reservoir heat pipes includes cooling fins positioned within the fluid reservoir.

4. The system of claim 1, further comprising a fluid return line configured to direct fluid from the heat exchanger back into the fluid reservoir.

5. The system of claim 1, further comprising one or more underground heat pipes coupled directly to the heat exchanger.

6. The system of claim 1, wherein the pump includes a pump controller configured to control an amount of cooling provided to the edge data center container, including performing one or more of: adjusting a pump speed of the pump, retract one or more reservoir heat pipes from the fluid reservoir, adjust fins included on the one or more reservoir heat pipes included in the fluid reservoir, and disconnecting or connecting one or more underground heat pipes to the heat exchanger.

7. The system of claim 6, wherein the pump controller is configured to control the amount of cooling provided to the edge data center container based on one or more of a current environment temperature and a predicted future environment temperature.

8. The system of claim 6, wherein the pump controller is configured to control the amount of cooling provided to the edge data center container based on one or more of a current workload and a predicted future workload.

9. The system of claim 6, wherein the pump controller is configured to control the amount of cooling provided to the edge data center container based on one or more of a current error rate of the computing equipment and a predicted future error rate of the computing equipment.

10. The system of claim 1, further comprising one or more additional pumps for redundancy.

11. A method for cooling edge data center equipment, the method comprising:
circulating, via a pump, a cooling fluid between a fluid reservoir and a heat exchanger included in an edge data center container, wherein the heat exchanger is thermally coupled to computing equipment included in the edge data center container via a thermosiphon; and
adjusting, by a pump controller included on the pump, an amount of cooling provided to the edge data center container based on a received instruction.

12. The method of claim 11, wherein the fluid reservoir includes one or more reservoir heat pipes positioned underground and partially within the fluid reservoir and configured to cool the cooling fluid within the fluid reservoir via geothermal cooling.

13. The method of claim 11, wherein adjusting the amount of cooling provided to the edge data center container includes performing one or more of: adjusting a pump speed of the pump, retract one or more reservoir heat pipes from the fluid reservoir, adjust fins included on the one or more reservoir heat pipes included in the fluid reservoir, and disconnecting or connecting one or more underground heat pipes to the heat exchanger.

14. The method of claim 11, wherein adjusting the amount of cooling provided to the edge data center container is based on one or more of a current environment temperature and a predicted future environment temperature.

15. The method of claim 11, wherein adjusting the amount of cooling provided to the edge data center container is based on one or more of a current workload and a predicted future workload.

16. The method of claim 11, wherein adjusting the amount of cooling provided to the edge data center container is based on one or more of a current error rate of the computing equipment and a predicted future error rate of the computing equipment.

17. An apparatus comprising:
computing equipment;
a thermosiphon coupled to the computing equipment; and
a heat exchanger coupled to the computing equipment via the thermosiphon, wherein the heat exchanger is configured to couple to a fluid reservoir positioned underground, and wherein a pump circulates cooling fluid between the fluid reservoir and the heat exchanger.

18. The apparatus of claim 17, further comprising a fluid return line configured to direct fluid from the heat exchanger back into the fluid reservoir.

19. The apparatus of claim 17, wherein the heat exchanger is directly coupled to one or more underground heat pipes.

20. The apparatus of claim 17, wherein the pump includes a pump controller configured to adjust an amount of cooling provided to the computing equipment, including performing one or more of: adjusting a pump speed of the pump, retract one or more reservoir heat pipes from the fluid reservoir, adjust fins included on the one or more reservoir heat pipes included in the fluid reservoir, and disconnecting or connecting one or more underground heat pipes to the heat exchanger.
